(19) United States
(12) Patent Application Publication
(10) Pub. No.: US 2004/0195650 A1
(43) Pub. Date: Oct. 7, 2004

(54) High-Q inductor device with a shielding pattern embedded in a substrate

(76) Inventors: Tsung-Ju Yang, Hsinchu (TW); Wei-Fu Huang, Kaohsiung (TW); Hsiang-Tsu Chen, Tainan (TW); Chang-Feng Hsu, Hsinchu (TW); Kuo-Chung Huang, Taoyuan (TW)

Correspondence Address: MARTINE & PENILLA, LLP, 710 LAKEWAY DRIVE, SUITE 170, SUNNYVALE, CA, 94085, US

(21) Appl. No.: 10/406,939

(22) Filed: Apr. 4, 2003

(51) Int. Cl. H01L 29/00

(52) U.S. Cl. 257/531

(57) ABSTRACT

An insulating layer is formed over a surface of a semiconductor substrate. A conductive film is formed over the insulating layer and separated from the semiconductor substrate. A shielding pattern is embedded within the semiconductor substrate and includes a plurality of isolation portions and a plurality of highly doped portions. The isolation portions are distributed within the semiconductor substrate for dividing the surface of the semiconductor into a plurality of regions unconnected with each other. The highly doped portions are formed within the semiconductor substrate and close to the surface, electrically insulated from each other by the isolation portions. The shielding pattern may further include a plurality of silicide layers formed on the highly doped portions and an ion implanted well for accommodating the isolation portions and the highly doped portions.

### BACKGROUND OF THE INVENTION

1. Field of the Invention

The present invention relates to an inductor device and, more particularly, to an inductor device with a shielding pattern embedded in a substrate for radio frequency integrated circuits so as to reduce a loss of energy stored in the inductor device, thereby enhancing a quality factor of the inductor device.

2. Description of the Related Art

In application of radio frequency integrated circuits, not only active devices such as diodes and transistors and passive devices such as resistors and capacitors are utilized, but various inductor devices such as coils and transformers are also employed. FIG. 1(a) is a perspective view showing a conventional inductor device 10. Referring to FIG. 1(a), the conventional inductor device 10 includes a semiconductor substrate 11, an insulating layer 12, and a conductive film 13. The insulating layer 12 is deposited on the semiconductor substrate 11 in order to isolate the conductive film 13 from the semiconductor substrate 11. The conductive film 13 is formed on the insulating layer 12 to have two terminals A and B. In the inductor device 10, the conductive film 13 serves a current path for providing an inductance effect. Typically, the conductive film 13 is formed in shape of a spiral belt as shown in FIG. 1(a), but may be any desirable shape.

FIG. 1(b) is an equivalent circuit diagram showing the conventional inductor device of FIG. 1(a). Referring to FIG. 1(b), symbols A and B represents two terminals of the conductive film 13, respectively. Symbols Rs and Ls represents an equivalent resistance and an equivalent inductance of the conductive film 13, respectively. Symbol Cs represents an equivalent inductance caused by overlaying between an underpass and an upper portion of the conductive film 13. Symbol Cox represents an equivalent capacitance formed between the semiconductor substrate 11 and the conductive film 13. Symbols Csi and Rsi represents an equivalent inductance and an equivalent resistance of the semiconductor substrate 11, respectively. Each of the equivalent circuit symbols shown in FIG. 1(b) is correspondingly illustrated in FIG. 1(a) for more apparently indicating the physical meanings thereof.

With the circuit theory, the equivalent circuit shown in FIG. 1(b) may be further reduced into an equivalent circuit shown in FIG. 1(c). Referring to FIG. 1(c), the capacitor Cox, the capacitor Csi, and the resistor Rsi may be reduced into a capacitor Cp and a resistor Rp connected in parallel.

$$\begin{matrix}{R}_{p} = \frac{1}{{ω}^{2} {C}_{ox}^{2} {R}_{si}} + \frac{{{R}_{si} ( {C}_{ox} + {C}_{si} )}^{2}}{{C}_{ox}^{2}} & ( 1 ) \\ {C}_{p} = {C}_{ox} \cdot \frac{1 + {ω}^{2} ( {C}_{ox} + {C}_{si} ) {C}_{si} {R}_{si}^{2}}{1 + {{ω}^{2} ( {C}_{ox} + {C}_{si} )}^{2} {R}_{si}^{2}} & ( 2 )\end{matrix}$$

In addition, according to the electromagnetic theory, a quality factor Q of the inductor device 10 may be expressed in the following equation:

$$Q = \frac{ω {L}_{s}}{{R}_{s}} \cdot \frac{{R}_{p}}{{R}_{p} + [ {( ω {L}_{s} / {R}_{s} )}^{2} + 1 ] {R}_{s}} \cdot [ 1 - \frac{{R}_{s}^{2} ( {C}_{s} + {C}_{p} )}{{L}_{s}} - {ω}^{2} {L}_{s} ( {C}_{s} + {C}_{p} ) ] \qquad ( 3 )$$

wherein the second multiplier term represents a semiconductor substrate loss factor and the third multiplier term represents a self-resonance factor.

As can be seen from Equation (3) and FIG. 1(c), in order to obtain a higher quality factor Q, it is necessary to raise the value of Rp and decrease the value of Cp. Moreover in accordance with Equation (1), if the value of Rsi decreases, i.e., the semiconductor substrate loss decreases, the value of Rp is raised. Based on such theory, a shielding pattern has been recently suggested to arrange in the conventional inductor device 10 for reducing the semiconductor substrate loss (reducing the value of Rsi), thereby increasing the quality factor Q, as described in detail later.

FIG. 2 is a perspective view showing a conventional shielding pattern 14 arranged in the conventional inductor device 10 of FIG. 1(a). Referring to FIG. 2, the shielding pattern 14 is embedded within the insulating layer 12 and located right under the conductive film 13. The shielding pattern 14 is made of a low resistance material such as metal or polysilicon and connected to ground. Since the shielding pattern 14 blocks electric field lines from the conductive film 13 for preventing the electric field lines from penetrating into the semiconductor substrate 11, the semiconductor substrate 11 causes no energy loss, i.e., the value of Rsi seems reduced to zero. As a result, the conventional inductor device 20 provided with the shielding pattern 14 can achieve a higher quality factor Q.

However, the arrangement of the shielding pattern 14 causes a formation of a parasitic capacitor between the shielding pattern 14 and the conductive film 13, resulting in an increase of Cp. The quality factor Q is therefore deteriorated.

### SUMMARY OF THE INVENTION

In view of the above-mentioned problem, an object of the present invention is to provide an inductor device with a shielding pattern embedded in a semiconductor substrate, capable of reducing not only an energy loss caused by the semiconductor substrate but also a parasitic capacitor caused by the shielding pattern, thereby achieving a relatively high quality factor.

According to one aspect of the present invention, a high-Q inductor device is provided, including a semiconductor substrate, an insulating layer, a conductive film, and a shielding pattern. The insulating layer is formed over a surface of the semiconductor substrate. The conductive film is formed over the insulating layer and separated from the semiconductor substrate. The shielding pattern is embedded in the semiconductor substrate and includes a plurality of isolation portions and a plurality of highly doped portions. The isolation portions is distributed in the semiconductor substrate, each of which has a bottom and a top. The bottom intrudes the semiconductor substrate while the top appears from the surface, thereby dividing the surface into a plurality of regions unconnected with each other. The highly doped portions is formed in the semiconductor substrate and close to the surface, each of which is electrically insulated from each other by the isolation portions.

The shielding pattern may further include a plurality of silicide layers formed on the highly doped portions, each of which is electrically insulated from each other by the isolation portions.

The shielding pattern may further include an ion implanted well formed in the semiconductor substrate for accommodating the isolation portions and the highly doped portions.

In the shielding pattern according to the present invention, all of the highly doped portions, the ion implanted well, and the salicide layers are low resistance structures so the surface layer of the semiconductor substrate has a resistance reduction. As a result, the electric field lines from the conductive film are successfully blocked and prevented from more deeply penetrating into the semiconductor substrate. Consequently, the energy loss caused by the semiconductor substrate is significantly reduced. Because the shielding pattern is embedded within the semiconductor substrate instead of the insulating layer, the distance between the shielding pattern and the conductive film becomes larger. As a result, the parasitic capacitor caused by the arrangement of the shielding pattern becomes smaller, thereby obtaining a relatively high quality factor.

The isolation portions cause the highly doped portions to be electrically insulated from each other and the salicide portions to be electrically insulated from each other. With such configuration, eddy currents are prevented from generating in the highly doped portions and the salicide layers.

### BRIEF DESCRIPTION OF THE DRAWINGS

The above-mentioned and other objects, features, and advantages of the present invention will become apparent with reference to the following descriptions and accompanying drawings, wherein:

FIG. 1(a) is a perspective view showing a conventional inductor device;

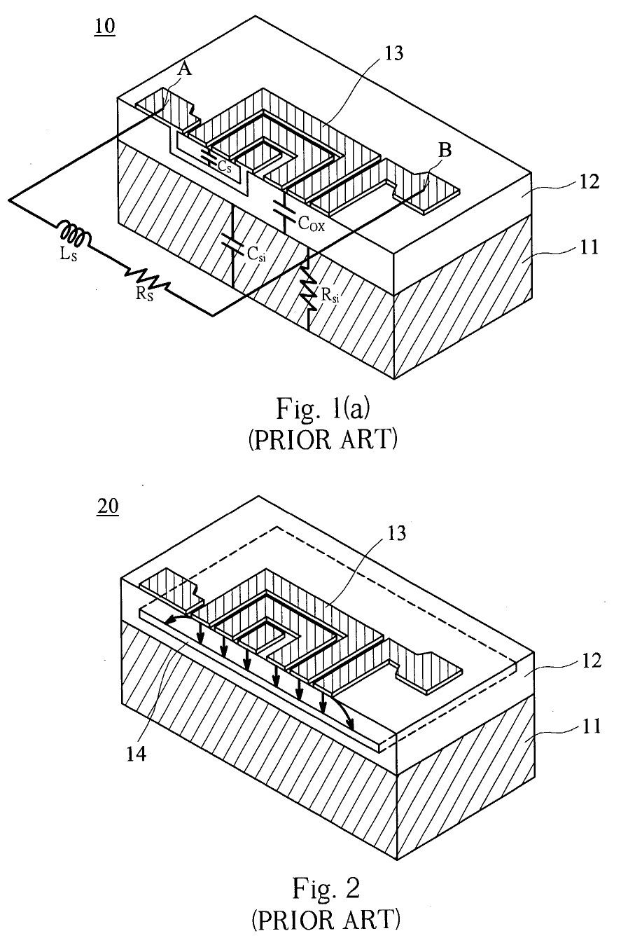

FIGS. 1(b) and 1(c) are diagrams showing two equivalent circuits of the conventional inductor device of FIG. 1(a);

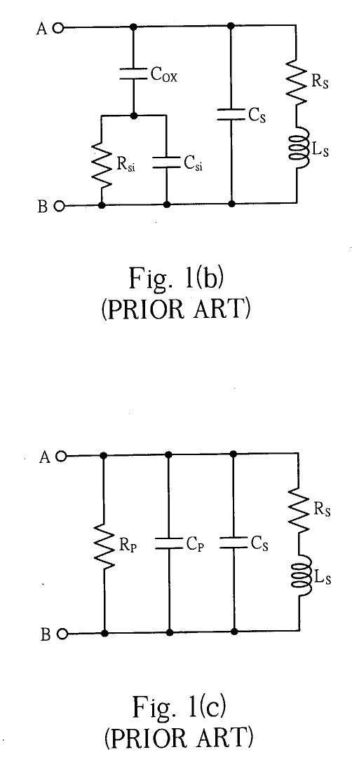

FIG. 2 is a perspective view showing a conventional shielding pattern arranged in the conventional inductor device of FIG. 1(a);

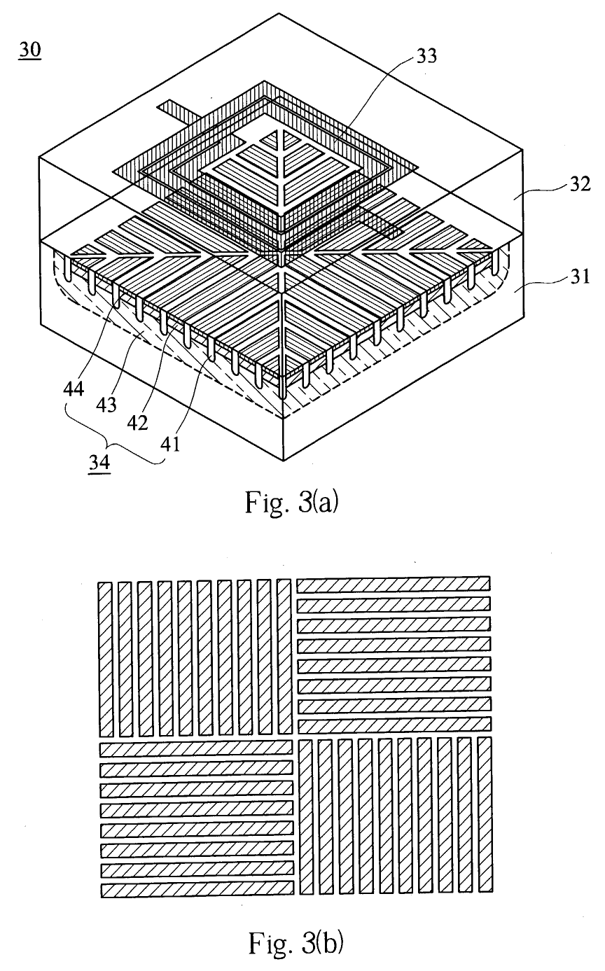

FIG. 3(a) is a perspective view showing an example of an inductor device with a shielding pattern embedded in a semiconductor substrate according to the present invention;

FIG. 3(b) is a top view showing another example of a shielding pattern according to the present invention; and

FIGS. 4(a) to 4(g) are cross-sectional views showing an example of method of fabricating an inductor device with a shielding pattern embedded in a semiconductor substrate according to the present invention.

### DETAILED DESCRIPTION OF THE PREFERRED EMBODIMENTS

The preferred embodiments according to the present invention will be described in detail with reference to the drawings.

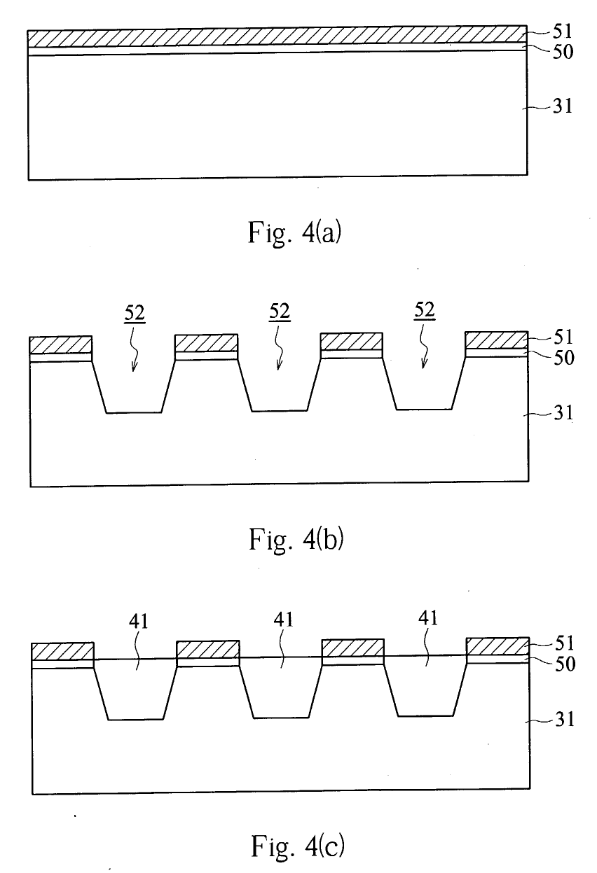

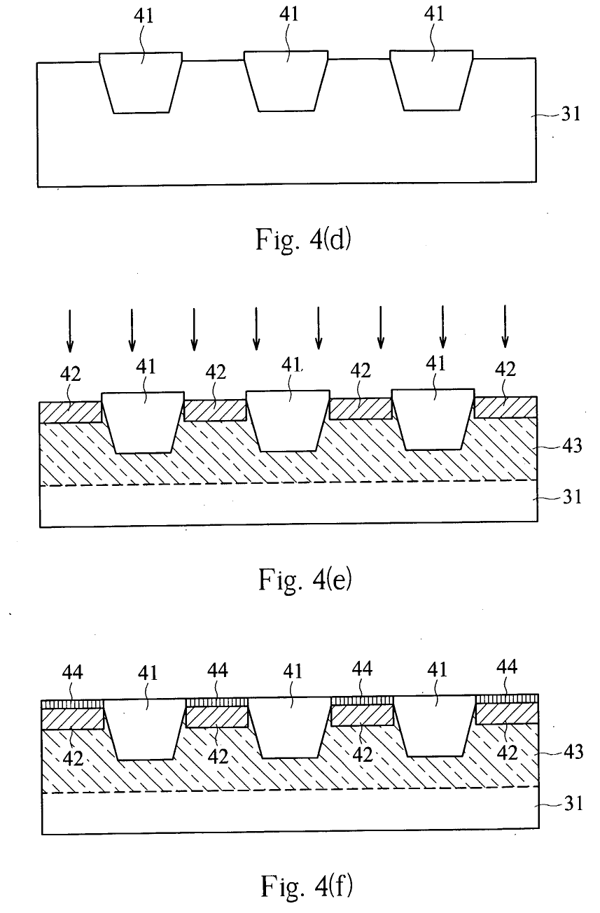

FIG. 3(a) is a perspective view showing an example of an inductor device 30 according to the present invention. Referring to FIG. 3(a), the inductor device 30 includes a semiconductor substrate 31 having a surface, an insulating layer 32, a conductive film 33, and a shielding pattern 34 embedded in the semiconductor substrate 31. For example, the semiconductor substrate 31 may be made of silicon and may have a P-type conductivity or an N-type conductivity. The insulating layer 32 is deposited over the surface of the semiconductor substrate 31 and may be made of an insulating material such as silicon oxide. The conductive film 33 is formed over the insulating layer 32 to separate from the semiconductor substrate 31. The conductive film 33 may be made of metal or alloy and have two terminals A and B, serving as a current path for providing an inductance effect. Typically, the conductive film 33 may be formed in shape of a spiral belt shown in FIG. 3(a), but may be formed in any desirable shape.

The shielding pattern 34 is embedded within the semiconductor substrate 31, primarily formed in the surface layer of the semiconductor substrate 31. The shielding pattern 34 includes a plurality of isolation portions 41, a plurality of highly doped portions 42, an ion implanted well 43, and a plurality of salicide layers 44. More specifically, the isolation portions 41 are distributed in the semiconductor substrate 31, each of which has a bottom intruding the semiconductor substrate 31 and a top appearing from the surface of the semiconductor substrate 31, thereby dividing the surface into a plurality of regions unconnected with each other. For example, the isolation portions 41 may be arranged either in form of a radiative matrix or as perpendicular to each other.

The highly doped portions 42 are formed within the semiconductor substrate 31 and close to the surface of the semiconductor substrate 31, each of which is electrically insulated from each other by the isolation portions 41. Each of the highly doped portions 42 has a conductivity of N-type or P-type. The highly doped portions 42 are formed in the unconnected regions divided by the isolation portions 41. Therefore, the highly doped portions 42 may be considered as arranged in a predetermined pattern.

The ion implanted well 43 is formed within the semiconductor substrate 31 right under the conductive film 33. The ion implanted well 43 must be deep enough for accommodating the isolation portions 41 and highly doped portions 42. The ion implanted well 43 may be an N-type well or a P-type well.

Each of the salicide layers 44 is formed on a surface of each of the highly doped portions 42 in order to effectively reduce the sheet resistance of the surface of the semiconductor substrate 31. For example, the salicide layers 44 may be made of titanium silicide.

In the present invention, the surface layer of the semiconductor substrate 31 under the conductive film 33 is embedded with the shielding pattern 34. Since all of the highly doped portions 42, the ion implanted well 43, and the salicide layers 44 included in the shielding pattern are low resistance structures, the surface layer of the semiconductor substrate 31 has a resistance reduction. As a result, the electric field lines from the conductive film 33 are successfully blocked and prevented from more deeply penetrating into the semiconductor substrate 31. Consequently, the energy loss caused by the semiconductor substrate 31 is significantly reduced.

Because the shielding pattern 34 according to the present invention is embedded within the semiconductor substrate 31 instead of the insulating layer 32, the distance between the shielding pattern 34 and the conductive film 33 becomes larger. As a result, the parasitic capacitor caused by the arrangement of the shielding pattern 34 becomes smaller, overcoming the problem of the conventional inductor device 20 and obtaining a relatively high quality factor.

It should be noted that, in the inductor device 30 according to present invention, the shielding pattern 34 may consist of the isolation portions 41, the highly doped portions 42, and salicide layers 44 and exclude the arrangement of the ion implanted well 43. Alternatively, the shielding pattern 34 may consist of the isolation portions 41 and the highly doped portions 42 and exclude the arrangement of the ion implanted well 43 and the salicide layers 44.

In the present invention, the isolation portions 41 of the shielding pattern 34 cause the highly doped portions 42 to be electrically insulated from each other and the salicide portions 44 to be electrically insulated from each other. With such configuration, eddy currents are prevented from generating in the highly doped portions 42 and the salicide layers 44.

It should be noted that the pattern constructed by the highly doped portions 42 and the salicide layers 44 of the shielding pattern 34 is not limited to that shown in FIG. 3(a), but may be any pattern capable of preventing the eddy currents. For example, FIG. 3(b) is a top view showing another example of the shielding pattern according to the present invention. Referring to FIG. 3(b), the hatched regions may indicate the highly doped portions 42, the salicide layers 44, or a combination thereof.

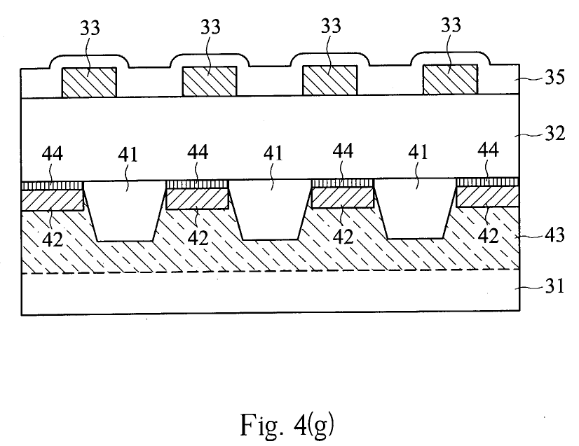

Hereinafter is described in detail an example of a method of fabricating an inductor device with a shielding pattern embedded in a semiconductor substrate with reference to FIGS. 4(a) to 4(g).

As shown in FIG. 4(a), a P-type silicon substrate 31 is prepared. In a surface of the P-type silicon substrate 31, a pad oxide layer 50 and a silicon nitride layer 51 are sequentially formed in a predetermined region on which an inductor device 30 according to the present invention is to be formed. For example, the pad oxide layer 50 has a thickness of about 110 angstroms while the silicon nitride 51 has a thickness of about 1,200 angstroms.

As shown in FIG. 4(b), a plurality of trenches 52 are formed in the P-type silicon substrate 31 through etching portions of the silicon nitride 51, the pad oxide 50, and the P-type silicon substrate 31. For example, each of the trenches 52 has a depth of about 3,600 angstroms, measured from the surface of the P-type silicon substrate 31.

As shown in FIG. 4(c), a plurality of shallow trench isolation portions 41 are formed through filling the plurality of trenches 52 with oxide by using a high density plasma.

As shown in FIG. 4(d), the remained portions of the pad oxide layer 50 and the silicon nitride layer 51 are removed such that the surface, on which no shallow trench isolation portions 41 are formed, of the P-type silicon substrate 31 exposes.

As shown in FIG. 4(e), an N-type ion implanted well 43 is formed in the P-type silicon substrate 31 through a first ion implantation (indicated by arrows shown in the figure). A depth of the N-type ion implanted well 43 is controlled to be larger than a depth of each of the shallow trench isolation portions 41. Thereafter, a plurality of N-type highly doped portions 42 are formed through a second ion implantation (indicated by arrows shown in the figure). A depth of the N-type highly doped portions 42 is controlled to be smaller than a depth of the shallow trench isolation portions 41 such that the N-type highly doped portions 42 are electrically insulated from each other by the shallow trench portions 41.

As shown in FIG. 4(f), a plurality of salicide layers 44 are formed on the N-type highly doped portions 42 through a well-known self-aligned silicide process. The salicide layers 44 are electrically insulated from each other by the shallow trench isolations 41.

As shown in FIG. 4(g), an insulating layer 32 is deposited over the surface of the P-type silicon substrate 31, thereby covering the shallow trench isolation portions 41 and the salicide layers 44. Subsequently, a conductive film 33 is formed over the insulating layer 32 in shape of a spiral belt. Therefore, the inductor device 30 according to the present invention is completed. In order to protect the inductor device 30, a passivation film 35 nay be formed to cover the spiral belt-like conductive film 33.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A high-Q inductor device, comprising:
a semiconductor substrate having a surface;
an insulating layer formed over the surface of the semiconductor substrate;
a conductive film formed over the insulating layer and separated from the semiconductor substrate, the conductive film having two terminals and serving as a current path; and
a shielding pattern embedded in the semiconductor substrate, including:
a plurality of isolation portions distributed in the semiconductor substrate, each of which has a bottom intruding the semiconductor substrate and a top appearing from the surface of the semiconductor substrate, thereby dividing the surface into a plurality of regions unconnected with each other, and
a plurality of highly doped portions formed in the semiconductor substrate and close to the surface, each of which is electrically insulated from each other through the plurality of isolation portions.

2. The high-Q inductor device according to claim 1, wherein the semiconductor substrate is made of silicon.

3. The high-Q inductor device according to claim 1, wherein the semiconductor substrate has a P-type conductivity and each of the plurality of the highly doped portions has an N-type conductivity.

4. The high-Q inductor device according to claim 1, wherein the semiconductor substrate has an N-type conductivity and each of the plurality of the highly doped portions has a P-type conductivity.

5. The high-Q inductor device according to claim 1, wherein each of the plurality of the isolation portions is formed of a shallow trench isolation.

6. The high-Q inductor device according to claim 1, wherein the plurality of the isolation portions are arranged in form of a radiative matrix.

7. The high-Q inductor device according to claim 1, wherein the plurality of the isolation portions are arranged as perpendicular to each other.

8. The high-Q inductor device according to claim 1, wherein the conductive film is formed in shape of a spiral belt.

9. The high-Q inductor device according to claim 1, further comprising:
a passivation layer for covering the conductive film.

10. The high-Q inductor device according to claim 1, wherein the shielding pattern further comprises:
a plurality of silicide layers formed on the plurality of the highly doped portions and electrically insulated from each other by the plurality of isolation portions.

11. The high-Q inductor device according to claim 10, wherein each of the plurality of silicide layers is formed of a salicide layer.

12. The high-Q inductor device according to claim 1, wherein the shielding pattern further comprises:
an ion implanted well formed in the semiconductor substrate for accommodating the plurality of isolation portions and the plurality of highly doped portions.

13. The high-Q inductor device according to claim 12, wherein the semiconductor substrate has a P-type conductivity, the ion implanted well has an N-type conductivity, and each of the plurality of the highly doped portions has an N-type conductivity.

14. The high-Q inductor device according to claim 12, wherein the semiconductor substrate has a P-type conductivity, the ion implanted well has an N-type conductivity, and each of the plurality of the highly doped portions has a P-type conductivity.

15. The high-Q inductor device according to claim 12, wherein the semiconductor substrate has an N-type conductivity, the ion implanted well has a P-type conductivity, and each of the plurality of the highly doped portions has a P-type conductivity.

16. The high-Q inductor device according to claim 12, wherein the semiconductor substrate has an N-type conductivity, the ion implanted well has a P-type conductivity, and each of the plurality of the highly doped portions has an N-type conductivity.
